(19) United States
(12) Patent Application Publication
(10) Pub. No.: US 2010/0229947 A1
(43) Pub. Date: Sep. 16, 2010

(54) Optical Element with a Reflective Surface Coating for Use in a Concentrator Photovoltaic System

(75) Inventor: Steven Seel, Albuquerque, NM (US)

Correspondence Address: EMCORE CORPORATION, 1600 EUBANK BLVD, S.E., ALBUQUERQUE, NM, 87123, US

(73) Assignee: Emcore Solar Power, Inc., Albuquerque, NM (US)

(21) Appl. No.: 12/402,814

(22) Filed: Mar. 12, 2009

(51) Int. Cl. H01L 31/00

(52) U.S. Cl. 136/259

(57) ABSTRACT

An optical element for use in a concentrating photovoltaic system for converting incident solar radiation to electrical energy. The optical element may include an entry aperture for receiving light beams from a primary focusing element, and an exit aperture for transmitting light beams to a solar cell. The optical element may also include an intermediate section whereby at least some of the light beams reflect off the intermediate section and are transmitted to the solar cell. This region may be composed of a layered structure with a first material layer having a first optical characteristic, and a second material layer having a second optical characteristic. The material composition and thickness of the layers may be adapted so that the reflectivity of the light beams off the surfaces and transmitted to the solar cell optimizes the aggregate irradiance on the surface of the solar cell over the incident solar spectrum.

### REFERENCE TO RELATED APPLICATIONS

This application is related to U.S. patent application Ser. No. 12/069,642 filed Feb. 11, 2008 and Ser. No. 12/264,369 filed Nov. 4, 2008. Each of these applications was filed by the assignee of the present application.

### BACKGROUND

A photovoltaic system converts sunlight into electrical energy. The system generally includes lenses that are each aligned to concentrate the sunlight onto a corresponding solar cell. The lenses and solar cells are normally mounted within a frame with the lenses being spaced away from the solar cell receivers. The number of lenses and solar cells may vary depending upon the desired electrical output. Further, the lenses and solar cells may be mounted on a support structure that moves such that the lenses remain facing towards the sun during the progression of the day. The solar cells may be multi-junction solar cells made of III-V compound semiconductors.

In some cases, the lenses do not focus light on a spot that is of the dimensions of the solar cells. This may occur due to a variety of causes, including but not limited to chromatic aberration of the lenses, misalignment of the solar cells relative to the lenses during construction or during operation due to tracker error, structural flexing, and wind load. To compensate for this, an optical element may be positioned between each lens and solar cell. The optical elements act as a light spill catcher to cause more of the light to reach the solar cells.

One common design for an optical element is a highly reflective mirror with a protective coating. Some previous designs include the mirror being a silver-coated aluminum sheet metal coated with a protective layer of aluminum oxide. The reflectivity of these optical elements over a wavelength range of 400 nm to 1900 nm is on average about 95%. However, below 400 nm, the reflectivity at normal incidence may drop precipitously to about 30% at 350 nm.

The III-V solar cells may include a top cell InGaP layer that collects light from 350 nm to about 675 nm to create photon generated carriers. If the optical element does not effectively reflect the light below 400 nm, then the solar cell does not operate at peak efficiency.

Therefore, there is a need for an optical element that reflects light at various wavelengths to a solar cell for the solar cell to operate efficiently.

### SUMMARY

The present application is directed to an optical element for use in a concentrated photovoltaic system. The system may include a primary focusing element for collecting the incident solar radiation and directing such radiation to the surface of a solar cell for conversion into electrical energy. The optical element may be positioned between the primary focusing element and the solar cell and may include an entry aperture for receiving light beams from the primary focusing element, and an exit aperture for transmitting light beams to the solar cell. The optical element may also include a region whereby at least some of the light beams are reflected and are transmitted to the solar cell. This region may be composed of a layered structure with a first material layer having a first optical characteristic, and a second material layer having a second optical characteristic. The material composition and thickness of each layer may be adapted so that the reflectivity of the light beams off the region and transmitted to the solar cell optimizes the aggregate irradiance on the surface of the solar cell over the incident solar spectrum.

The various aspects of the various embodiments may be used alone or in any combination, as is desired.

### BRIEF DESCRIPTION OF THE DRAWINGS

FIG. 1A is a schematic diagram of an optical element, solar cell, and primary focusing element with an ideal arrangement between the primary focusing element and the solar cell according to one embodiment.

FIG. 1B is a schematic diagram of an optical element, solar cell, and primary focusing element with a common arrangement between the primary focusing element and the solar cell according to one embodiment.

FIG. 2 is a perspective view of an optical element according to one embodiment.

FIG. 3 is a schematic cross-sectional view of an intermediate member and first layer of a prior art optical element.

FIG. 4 is a partial cross-sectional view cut along line III-III of FIG. 2 of an intermediate section of an optical element with a first layer according to one embodiment.

FIG. 5 is a partial cross-sectional view of an intermediate section with first and second layers according to one embodiment.

FIG. 6 is a schematic cross-sectional view of an intermediate member, first layer, and second layer of an optical element according to one embodiment.

FIG. 7 is a graph illustrating reflectance at normal incidence at various wavelengths for various materials.

FIG. 8 is a cut-away perspective view of optical elements positioned between primary focusing elements and solar cells according to one embodiment.

### DETAILED DESCRIPTION

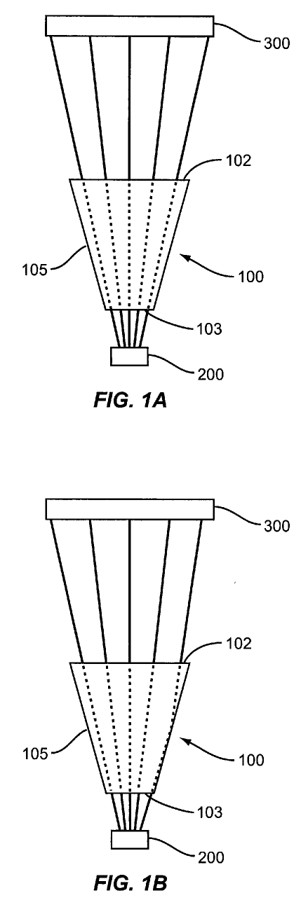

FIG. 1A includes a schematic view of an optical element 100 positioned between a solar cell 200 and a primary focusing element 300. The optical element 100 includes an entry aperture 102 that receives light beams from the primary focusing element 300 and an exit aperture 103 that transmits the light beams to the solar cell 200. The optical element 100 includes an intermediate region 105 between the apertures 102, 103. FIG. 1A includes an ideal condition with the primary focusing element 300 focusing the light directly to the solar cell 200 without the light hitting against the optical element 100.

In most circumstances, the primary focusing element 300 does not focus light directly on the solar cell 200. This may occur due to a variety of causes, including but not limited to chromatic aberration of a refractive lens design, misalignment of the solar cell 200 relative to the primary focusing element 300 during construction, misalignment during operation due to tracker error, structural flexing, and wind load. FIG. 1B illustrates an embodiment with the primary focusing element 300 focusing the light such that it reflects off the optical element 100. The difference between an ideal setup of FIG. 1A and the embodiment of FIG. 1B may be a minor variation in the positioning of the primary focusing element 300 of less than 1°.

The optical element 100 therefore acts as a light spill catcher to cause more of the light to reach the solar cell 200 in circumstances when the primary focusing element 300 does not focus light directly on the solar cell 200. The optical element 100 includes a reflective multi-layer intermediate region 105. The layers are formed from different materials and have different optical characteristics. The material composition and thickness of each layer is adapted so the reflectivity of the light beams off optical element 100 and transmitted to the solar cell 200 optimizes the aggregate irradiance on the surface of the solar cell 200 over the incident solar spectrum.

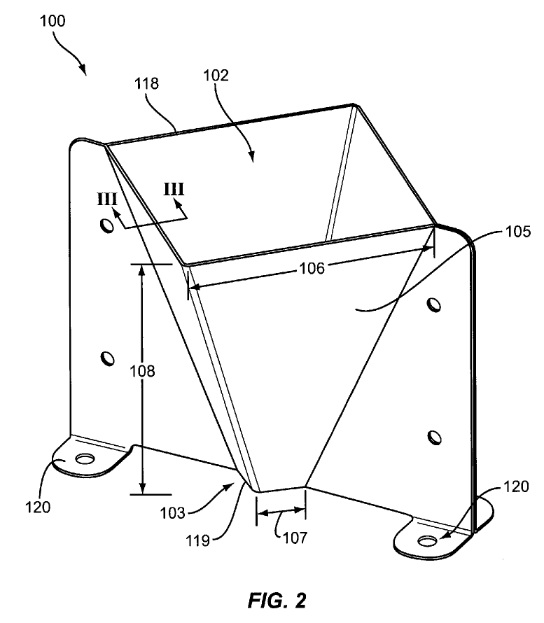

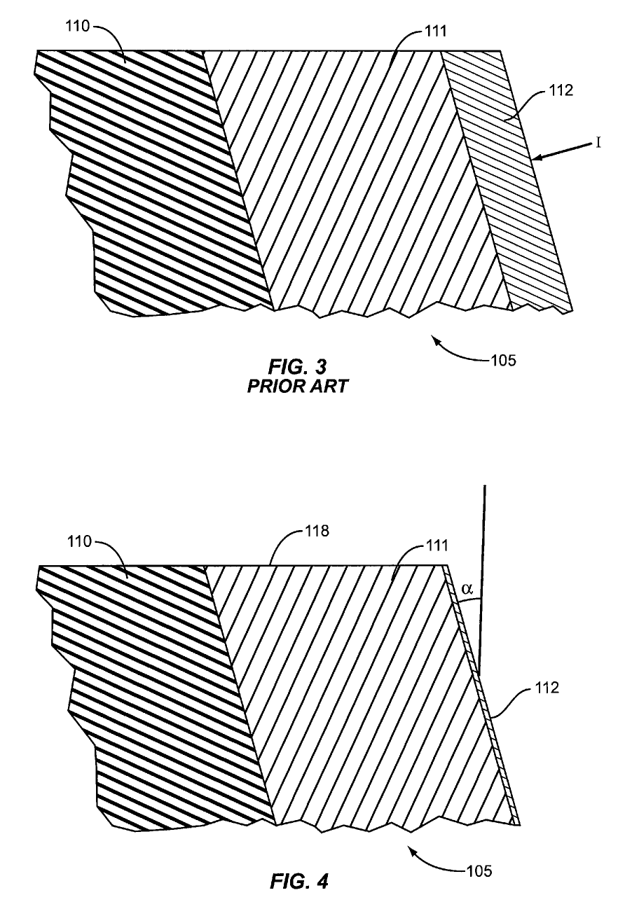

FIG. 2 illustrates an optical element 100 that includes the entry aperture 102, opposing exit aperture 103, and the intermediate region 105. The intermediate region 105 includes sides each with inner surfaces that face inward towards a center of the hollow optical element 100. The optical element 100 includes a height 108 measured between a top edge 118 and a bottom edge 119. The optical element 100 includes a generally square cross-sectional shape that tapers from the entry aperture 102 to the exit aperture 103. In one embodiment, the entry aperture 102 is square-shaped and is about 49.60 mm×49.60 mm (dimension 106), the optical outlet is square-shaped and is about 9.9 mm×9.9 mm (dimension 107) and the height 108 is about 70.104 mm. The dimensions 106, 107 and 108 may vary depending with the design of the photovoltaic system. In one embodiment, the dimensions of the exit aperture 103 are approximately the same as the dimensions of the solar cell 200.

The optical element 100 may include various cross-sectional shapes and may include a variety of different sides. FIG. 2 includes a square cross-sectional shape with four sides. Another example includes a three-sided optical element 100 with a triangular cross-sectional shape.

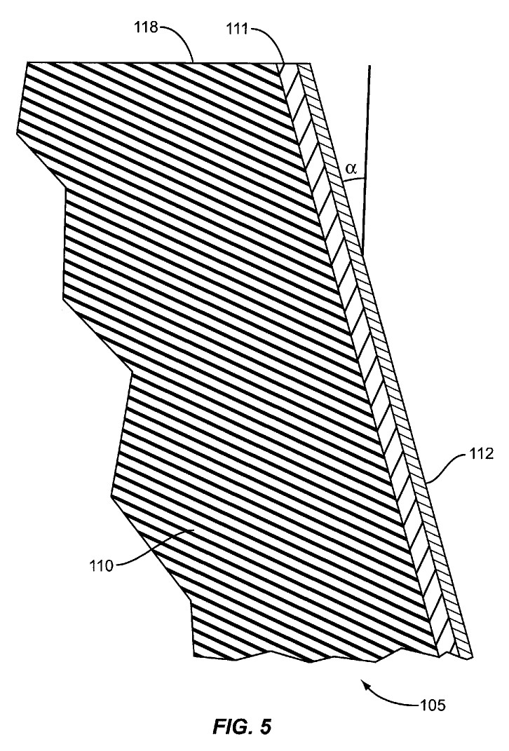

FIG. 3 includes a schematic cross-sectional diagram of a prior art intermediate region 105 that includes a substrate 110, a first layer 111, and a second layer 112. The substrate 110 is aluminum with a silver first layer 111 with a thickness of about 1000 nm. An aluminum-oxide second layer 112 with a thickness of about 250 nm is positioned over the first layer 111. This intermediate section design results in a reflectivity of an incoming beam I at 350 nm at normal incidence of only about 30% as a majority of the light beam is absorbed.

FIG. 4 illustrates one embodiment of the present application of the layered intermediate region 105. The intermediate region 105 includes an aluminum substrate 110 with a silver first layer 111. The second layer 112 is positioned on the surface of the first layer 111 and improves the reflectivity, and also protects the surface of the first layer 111. In one embodiment, the second layer 112 is aluminum-oxide. Optimizing the thickness of the second layer 112 increases the reflectivity of incoming light at glancing angles α. Glancing angles α are the angle of the incoming light beams with respect to the plane of the surface of the intermediate section 105. In one embodiment, the first layer 111 includes a thickness of about 1000 nm, and the second layer 112 includes a thickness that ranges from between about 12 nm and about 22 nm. In one specific embodiment with a glancing angle α of about 15 degrees and a silver first layer 111 with a thickness of about 1000 nm and an aluminum-oxide second layer 112 with a thickness of about 17 nm results in a reflectivity of about 94% at 450 nm, about 92% at 400 nm, and about 74% at 375 nm.

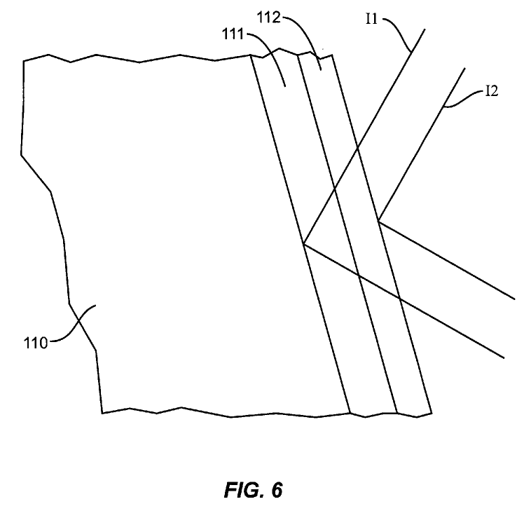

FIG. 5 illustrates another embodiment with a layered intermediate region 105 that includes an aluminum substrate 110 and first and second layers 111, 112. In one embodiment, the first layer 111 is silver with a thickness of between about 20 nm and about 30 nm. In one specific embodiment, the first layer 111 includes a thickness of about 25 nm. The second layer 112 is positioned on the surface of the first layer 111. The second layer 112 is aluminum oxide with a thickness of about 17 nm. A glancing angle α of about 15 degrees with this specific embodiment results in a reflectivity of about 95% at 450 nm, about 93% at 400 nm, and about 82% at 375 nm. In another embodiment, with a glancing angle of less than 30 degrees, the reflectivity exceeds a value of about 80% in the spectral range of 350 nm-400 nm, and exceeds about 90% in the spectral range of 400 nm-1900 nm.

In the embodiment of FIG. 4, the relatively thick first layer 111 results in no light reaching the aluminum substrate 110. Therefore, the aluminum substrate 110 does not impact the reflectivity. The embodiment of FIG. 5 reduces the thickness of the first layer 111 resulting in part of the light being transmitted through the first layer 111 and reflecting off the aluminum substrate 110. The consequence is an improvement in blue reflectivity with only a small degradation in the red reflectivity.

The first material layer 111 is constructed to have a first optical characteristic, and the second material layer 112 is constructed to have a second optical characteristic. The material composition and thicknesses of the layers 111, 112 may result in optical characteristics for the absorption of light in the spectral band from 350 nm to 1900 nm and/or the reflectivity of light in the same spectral band. FIG. 6 illustrates a schematic cross-sectional view of one embodiment with a first incoming light beam I1 at a first wavelength may be reflected by the substrate 110, and a second incoming light beam I2 at a second wavelength may be reflected by the second layer 112. In one embodiment, the second layer 112 reflects a first portion of light to the solar cell 200 and transmits a second portion of the light to the first material layer 111, and the first material layer 111 reflects a third portion of the light back through the second material layer 112 to the solar cell 200.

In some embodiments, the second material layer 112 may reflect a first portion of the incoming light to the solar cell 200, and transmit a second portion of the incoming light to the first material layer 111. The first material layer 111 then reflects a third portion of the incoming light back through the second material layer 112 to the solar cell 200. In one embodiment, the second material layer 112 is optimized to transmit a predetermined portion of the incoming light to the first material layer 111.

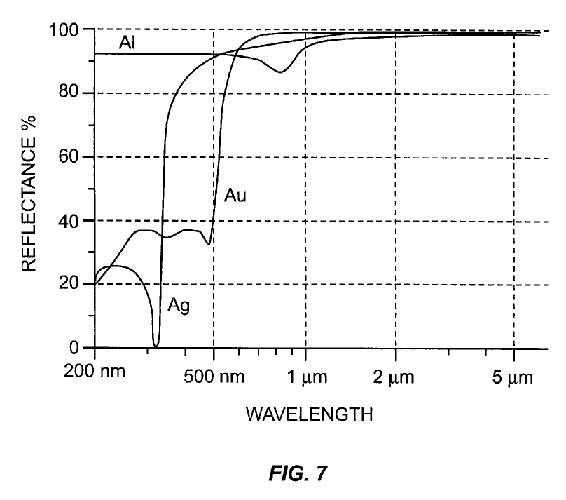

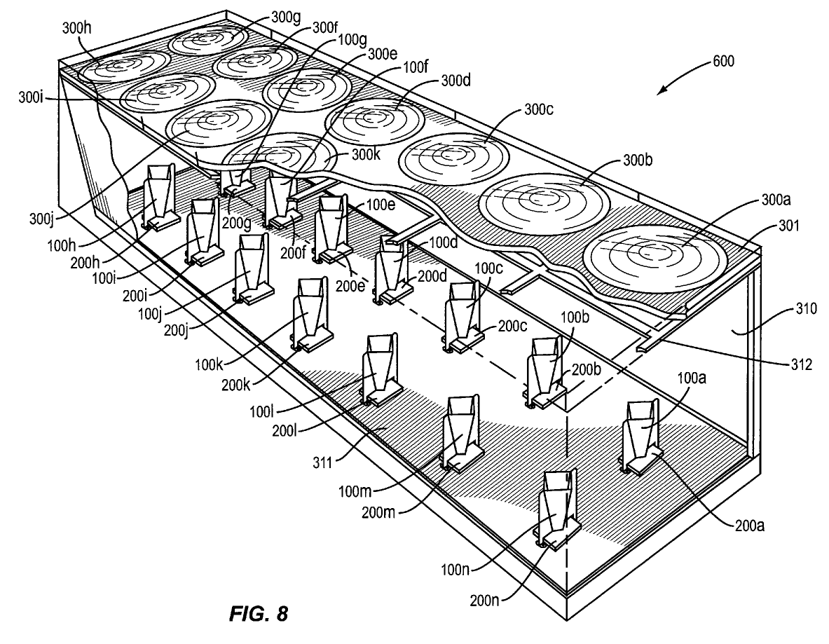

FIG. 7 includes the reflectance at normal incidence of various materials at different wavelengths. By optimizing the thickness of the silver and alumina layers in an alumina-silver-aluminum mirror stack, the absolute reflectance of glancing angles can be improved at a variety of wavelengths. The improvement of the optical element 100 can substantially improve III-V concentrator photovoltaic performance, especially during the winter months and early/late in the day when the spectrum is blue-poor. Glancing angle reflectivity for a typical alumina-coated silver mirror with a 250 nm alumina layer over a 1000 nm silver layer as schematically illustrated in FIG. 3 is about 91% at 450 nm, about 85% at 400 nm, and about 60% at 375 nm. Therefore, an embodiment as illustrated in FIG. 5 improves reflectance by about 4% at 450 nm, about 8% at 400 nm, and about 22% at 375 nm.

FIG. 8 illustrates sets of optical elements 100a-100n (collectively referred to as optical elements 100) positioned between corresponding primary focusing elements 300a-300j (four of which are not shown)(collectively referred to as focusing elements 300) and corresponding solar cells 200a-200n (collectively referred to as solar cells 200). In some implementations, a photovoltaic system may include one or more modules 600 that each comprises fourteen sets of optical elements 100, primary focusing elements 300, and solar cells 200. The embodiment of FIG. 8 includes the sets configured in an array of 2×7.

The primary focusing elements 300 are positioned above the optical elements 100 and concentrate sunlight onto the solar cells 200. The primary focusing elements 300 may be Fresnel lenses, or may be conventional spherical lenses. An advantage of Fresnel lenses is they require less material compared to a conventional spherical lens and may weight less. The primary focusing elements 300 may be constructed from a variety of materials, including but not limited to acrylic, plastic, and glass. The primary focusing elements 300 may also comprise a multi-layer anti-reflective coating.

The primary focusing elements 300 may be combined with a parquet member 301 to form an integral lens sheet. The parquet member 301 includes apertures that are each sized to receive one of the elements 300. In one embodiment, each aperture is substantially circular and sized to accommodate a rectangular primary focusing element 300. In one embodiment, each primary focusing element 300 is 9 inches by 9 inches. It is understood that the primary focusing elements 300 may also include different shapes and sizes.

The integral lens sheet is attached to a housing 310 with each of the primary focusing elements 300 positioned over and aligned with one of the optical elements 100 and solar cell receivers 200 that are mounted below to a support surface 311. The integral lens sheet may be supported on its peripheral edges by the housing 310 and may lie atop a frame 312 that extends across a top of the housing 310. Forming the primary focusing elements 300 in an integral sheet may be advantageous because production costs may be decreased, and assembly costs may be decreased because only one item (i.e., the integral lens sheet) needs to be aligned with the optical elements 100 and solar cells 200. U.S. Patent Ser. No. ______ (Emcore Docket No. 8404) discloses various embodiments of integral lens sheets and is herein incorporated by reference.

The optical elements 100 may each include mounting tabs 120 (FIG. 2) to attach to the support surface 311. In one embodiment, the mounting tabs 120 include apertures sized to receive a fastener to attach the optical element to the support surface 311. While it may vary depending up the specific context of use, each of the optical elements 100 may be mounted with the bottom edge 119 about 0.5 mm from the solar cells 200.

The solar cells 200 are positioned on the support surface 311 and each is aligned with one of the optical elements 100 and primary focusing elements 300. The solar cells 200 may each include a triple-junction III-V compound semiconductor solar cell with top, middle, and bottom cells arranged in series. The solar cells 200 may be incorporated into a receiver as disclosed in U.S. Patent Ser. No. ______ (Emcore Docket No. 7401) which is herein incorporated by reference. Each solar cell 200 is positioned to receive focused solar energy from the primary focusing elements 300 and/or the optical elements 100. In applications where multiple solar cell modules are employed, the solar cells 200 are typically electrically connected together in series. However, other applications may utilize parallel or series-parallel connection. For example, solar cells 200 within a given module 600 can be electrically connected together in series, but the modules 600 are connected to each other in parallel.

The distance between the primary focusing elements 300 and the corresponding solar cells 200 can be chosen, e.g., based on the focal length of the elements 300. In some implementations the housing 310 is arranged so that the solar cells 200 are disposed at or about the focal point of the respective primary focusing element 300. In some implementations, the focal length of each primary focusing element 300 is between about 25.4 cm (10 inches) and 76.2 cm (30 inches). In some implementations, the focal length of each primary focusing element is between about 38.1 cm (15 inches) and 50.8 cm (20 inches). In some implementations, the focal length of each primary focusing element 300 is about 40.085 cm (17.75 inches). In some implementations, the focal length of each primary focusing element varies, and the housing 310 provides multiple different distances.

Spatially relative terms such as “under”, “below”, “lower”, “over”, “upper”, and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The present invention may be carried out in other specific ways than those herein set forth without departing from the scope and essential characteristics of the invention. The optical element 100 may also homogenize (i.e., mix) the light, and may also include some concentration effect. The present embodiments are, therefore, to be considered in all respects as illustrative and not restrictive, and all changes coming within the meaning and equivalency range of the appended claims are intended to be embraced therein.

What is claimed is:

1. An optical device for use in a concentrating photovoltaic system for converting incident solar radiation to electrical energy, including a primary focusing element for collecting the incident solar radiation and directing such radiation to the surface of a solar cell, comprising:
an optical element having an entry aperture for receiving light beams from the primary focusing element, an exit aperture for transmitting light beams to the solar cell, and a region whereby at least some of the light beams reflect off the surface of said region and are transmitted to the solar cell, the region being composed of a layered structure with a first material layer having a first optical characteristic, and a second material layer disposed on said first material layer and having a second optical characteristic, wherein the material composition and thickness of each layer is adapted so that the reflectivity of the light beams off such surface and transmitted to the solar cell optimizes the aggregate irradiance on the surface of the solar cell over the incident solar spectrum.

2. The device of claim 1, wherein the first and second optical characteristic is the absorption of light in the spectral band from 350 nm to 1900 nm by the first and second material layers respectively.

3. The device of claim 1, wherein the first and second optical characteristic is the reflectivity of light in the spectral band from 350 nm to 1900 nm by the first and second material layers respectively.

4. The device of claim 1, wherein the reflectivity of the surface of said region at a glancing angle of an incoming light beam less than 30 degrees with respect to the plane of surface exceeds a value of 80% in the 350 to 400 nm spectral range, and exceeds 90% in the 400 to 1900 nm spectral range.

5. The device of claim 1, wherein the second material layer reflects a first portion of light to the solar cell and transmits a second portion of the light to the first material layer, and the first material layer reflects a third portion of the light back through the second material layer to the solar cell.

6. The device of claim 1, wherein the thickness of the second material layer is optimized to transmit a predetermined portion of light to the first material layer

7. The device of claim 1, wherein the optical element is formed by a tapering conduit having at least three planar inner sides and wherein said region is formed on the surface of said inner sides.

8. The device of claim 1, wherein a cross sectional shape of the optical element parallel to a plane of the solar cell is geometrically similar to that of the solar cell.

9. The device of claim 8, wherein the cross sectional shape is square.

10. The device of claim 1, wherein the optical element is hollow.

11. An optical device for use in a concentrating photovoltaic system for converting incident solar radiation to electrical energy, including a primary focusing element for collecting the incident solar radiation and directing such radiation to the surface of a solar cell, comprising:
an optical element with an entry aperture for receiving light beams from the primary focusing element and an exit aperture for transmitting the light beams to the solar cell, the optical element including a tapered shape that reduces in size from the entry aperture to the exit aperture with sidewalls that extend between the entry aperture and exit aperture, the sidewalls being reflective and including a first material layer having a first optical characteristic and a second material layer disposed on said first material layer and having a second optical characteristic, the sidewalls being constructed to reflect the light beams that enter through the entry aperture to the solar cell.

12. The optical device of claim 11, wherein the optical element includes a polygonal cross-sectional shape.

13. The optical device of claim 11, wherein the second material layer reflects a first portion of light to the solar cell and transmits a second portion of the light to the first material layer, and the first material layer reflects a third portion of the light back through the second material layer to the solar cell.

14. The device of claim 11, wherein the second material layer includes a thickness to transmit a predetermined portion of light to the first material layer.

15. An optical element disposed in an optical path between a lens and a solar cell, the optical element configured to concentrate incoming light onto the solar cell and comprising:
a channel with an enlarged inlet that faces towards the lens and tapers to a reduced outlet that faces towards the solar cell, the channel including reflective inner walls;
first and second layers positioned on the reflective inner walls;
the layered reflective inner walls configured to reflect the incoming light that enters through the inlet towards the outlet and onto the solar cell, the layered reflective inner walls having a reflectivity at a glancing angle of the incoming light beam less than about 30 degrees with respect to inner wall being about 95% at 450 nm, about 93% at 400 nm, and about 82% at 375 nm.

16. The optical element of claim 15, wherein the layered inner walls include a reflectivity at normal incidence of about 95% over a wavelength range of 400 nm to 1900 nm.

17. The optical element of claim 15, wherein the channel includes a polygonal cross-sectional shape.

18. The optical element of claim 15, wherein the first layer includes silver and the second layer includes aluminum oxide.

19. The optical element of claim 18, wherein the first layer includes a thickness of about 25 nm and the second layer includes a thickness of about 17 nm.

20. The optical element of claim 15, wherein the channel further includes outwardly-extending opposing arms configured to attach the channel in the optical path.
